(19) United States
(12) Patent Application Publication
(10) Pub. No.: US 2012/0098080 A1
(43) Pub. Date: Apr. 26, 2012

(54) METHOD AND PACKAGE FOR AN ELECTRO-OPTICAL SEMICONDUCTOR DEVICE

(75) Inventors: ANDREW BUTTERFIELD, RIVERVIEW, FL (US); KARO KUJANPAA, MISSION, TX (US)

(73) Assignee: JABIL CIRCUIT, INC, ST. PETERSBURG, FL (US)

(21) Appl. No.: 12/912,207

(22) Filed: Oct. 26, 2010

(51) Int. Cl. H01L 31/0203; H01L 31/18

(52) U.S. Cl. 257/433; 438/66; 257/E31.117; 257/E31.001

(57) ABSTRACT

An electro-optical semiconductor device having a semiconductor die including an active region for detecting light which is covered by a cover. The cover has a transparent pane over the active region, and is supported by a standoff. The standoff sits on the die on a perimeter region between the active region and a plurality of bond pads disposed around the periphery of the die.

### BACKGROUND

The invention relates generally to electronics packaging, and more particularly to packaging electro-optical semiconductor devices.

Digital image sensors, such as those used in digital cameras and other multi-media devices, have seen a dramatic rise in popularity. Such devices are now commonly included in cellular and mobile telephone devices, laptop computers, and other such devices. Given the high volume at which image detecting devices are made, the cost of manufacturing them has increasingly become an important consideration for manufacturers. One of the critical aspects of high volume manufacturing is spoilage—the number or parts or sub-assemblies that have to be rejected for failure to meet specifications. Spoilage can be the result of tolerances falling out of specification, as well as parts being damaged during manufacture.

A conventional method of manufacturing and packaging digital image sensors is to fabricate a wafer containing a plurality of image detector dies which are separated and placed into respective lead frames. Each image detector die has a plurality of bonding pads which are typically wirebonded to corresponding pads of the lead frame. The wirebonding process must be carefully controlled to avoid producing any dust or debris which can fall on the image detector and damage the device, resulting in a defective image being produced. As a result, the process can be relatively expensive, and still not eliminate spoilage of units.

Furthermore, image detectors are typically packaged with a light-penetrable cover to protect them during manufacture and subsequent use once mounted in a device. The cover is supported over the image detector by a standoff or standoffs. A common way of forming covers is to create a standoff structure on a sheet of transparent material using a photolithography process. The photolithographic process involves spreading a layer of photocurable material on the transparent material, masking off the regions to be removed, curing the material, and then removing the excess material to leave the cured material forming the standoff. The photolithographic process is substantially involved, time consuming, and relatively costly.

Accordingly, there is a need for means to package electro-optical semiconductor devices which substantially avoids these and other problems associated with the prior art.

### SUMMARY OF THE INVENTION

Embodiments of the invention include a method for packaging an electro-optical device, a semiconductor image detector package, and an electronic device containing a semiconductor image detector. A method for packaging a semiconductor image sensor commences by providing a semiconductor image sensor die having an active region, a plurality of bonding pads disposed around a periphery of the die, and a perimeter region around the active region between the active region and the bonding pads. The method can then commence by providing a cover over the active region. The cover has a transparent pane situated over the active region of the die. The pane is supported by, and adhered to, a standoff. The standoff has a shape corresponding to the perimeter region of the die. The method can then commence by adhering the standoff to the perimeter region.

A semiconductor package embodiment can include a semiconductor image sensor die having a plurality of bonding pads disposed around a periphery of the die. The die further has an active region and a perimeter region around the active region between the active region and the bonding pads. The package can further include a cover disposed over the active region which has a transparent pane supported by, and adhered to, a standoff. The standoff has a shape corresponding to the perimeter region of the die. The standoff is adhered to the perimeter region. The standoff therefore forms a wall around between the active region of the die and the bonding pads, thereby protecting the active region during the wirebonding process.

An electronic device embodiment includes a housing containing a circuit board, on which an electro-optical semiconductor device is disposed. The electro-optical semiconductor device has a semiconductor image sensor die having a plurality of bonding pads disposed around a periphery of the die. The die further has an active region and a perimeter region around the active region between the active region and the bonding pads. The electro-optical semiconductor device can further include a cover disposed over the active region which has a transparent pane supported by, and adhered to, a standoff.

### BRIEF DESCRIPTION OF THE DRAWINGS

There are shown in the drawings, embodiments which are presently preferred, it being understood, however, that the invention is not limited to the precise arrangements and instrumentalities shown.

FIG. 1 shows a cross sectional view of an electro-optical semiconductor device with a cover, in accordance with an embodiment;

FIG. 2 shows a top plan view of an electro-optical semiconductor die, in accordance with an embodiment;

FIG. 3 shows an exploded isometric view of a cover for an electro-optical semiconductor device, in accordance with an embodiment;

FIG. 4 shows diagram of a molding process for creating a cover for an electro-optical semiconductor device, in accordance with an embodiment;

FIG. 5 shows an isometric cut-away view of a mold for creating a standoff for a cover for an electro-optical semiconductor device, in accordance with an embodiment;

FIG. 6 shows a side elevational view of a molding process for forming a cover for an electro-optical semiconductor device, in accordance with an embodiment;

FIG. 7 shows an isometric cut-away view of a grid of cells molded onto a sheet of transparent material for creating a cover for an electro-optical semiconductor device, in accordance with an embodiment;

FIG. 8 shows a grid of cells molded onto a sheet of transparent material for creating a cover for an electro-optical semiconductor device, in accordance with an embodiment;

FIG. 9 shows a side elevational view of a grid of cells molded onto a sheet of transparent material for creating a cover for an electro-optical semiconductor device, in accordance with an embodiment;

FIG. 10 shows a semiconductor wafer containing a plurality of electro-optical dies, in accordance with an embodiment;

FIG. 11 shows a side view of a process of placing covers on electro-optical semiconductor dies, in accordance with an embodiment;

FIG. 12 shows a side view of a process of placing covers on electro-optical semiconductor dies, in accordance with an embodiment;

FIG. 13 shows a flow chart diagram of a method of packaging an electro-optical semiconductor device, in accordance with an embodiment; and

FIG. 14 shows an electronic device utilizing an electro-optical device, in accordance with an embodiment.

### DETAILED DESCRIPTION OF THE DRAWINGS

While the specification concludes with claims defining features of the invention that are regarded as novel, it is believed that the invention will be better understood from a consideration of the description in conjunction with the drawings. As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting but rather to provide an understandable description of the invention.

Generally an electro-optical semiconductor device, such as an image detector, is configured to contain an active region which is electrically responsive to light on a semiconductor die. The die has a plurality of bonding pads disposed about the periphery of the die, and a perimeter region between the periphery and the active region. A cover is placed over the active region, and is comprised of a transparent pane which is supported over the active region by a standoff. The standoff is adhered to the die on the perimeter region between active region and the bonding pads on the periphery.

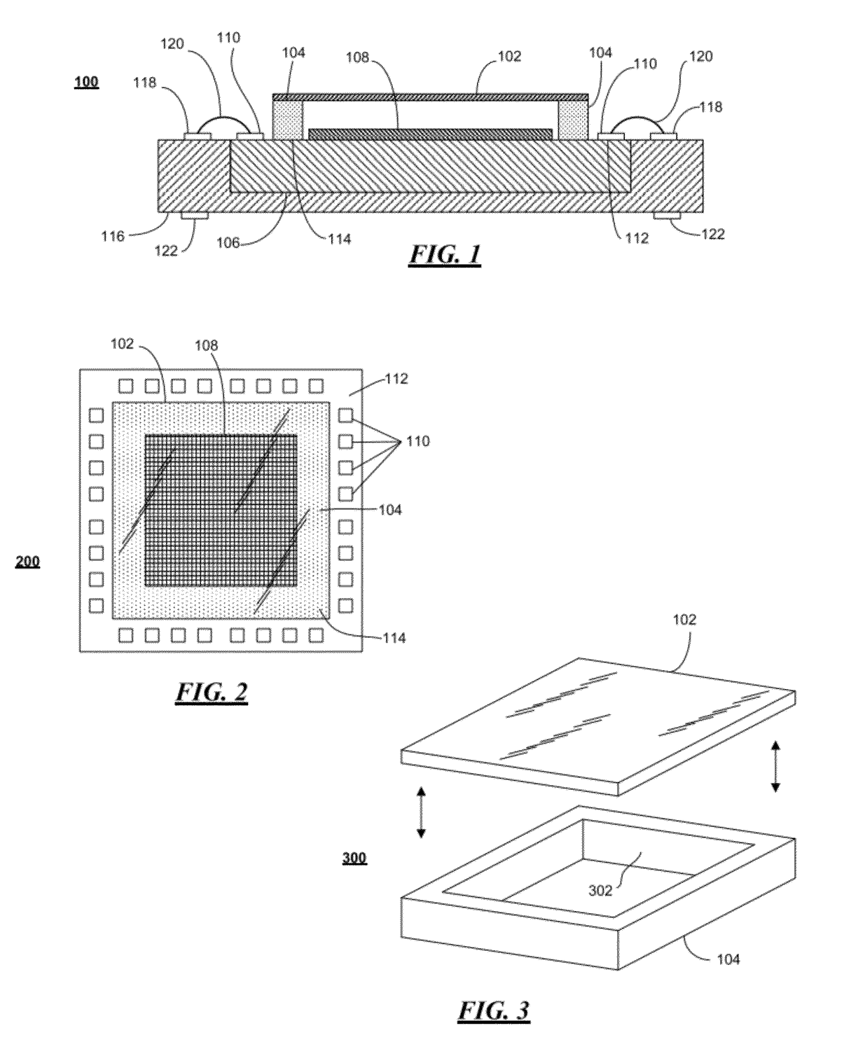

Referring to FIG. 1, there is shown a cross sectional view of an electro-optical semiconductor device 100 with a cover, in accordance with an embodiment. A transparent pane 102 is supported by a standoff 104 over an active region 108 of an electro-optical semiconductor die 106. The active region can be a photo or image sensor for producing digital images, such as found, for example, in digital cameras, and can be fabricated using Charge Coupled Device (CCD) and Complementary Metal-Oxide Semiconductor (CMOS) technologies. The active region is subdivided into discrete sensing units, which can correspond to pixels, and which produce a signal representative of the color and intensity of light incident thereon. Each such unit is electrically coupled through the semiconductor die to a bonding pad 110. A plurality of bonding pads are disposed about the periphery 112 of the die. The periphery includes a region of the top surface of the die near the edge of the die. A perimeter region 114 is formed between the bonding pads 110 and the active region 108. The standoff is shaped corresponding to the perimeter region and is adhered to the perimeter region. The standoff supports the transparent pane 108 and is adhered to the transparent pane. The transparent pane is formed of a transparent material, such as, for example, optical glass, and can have optical filter coatings, including an infrared (IR) filter coating. FIG. 2 shows a top plan view 200 of the electro-optical semiconductor die. The active region 108 can be generally disposed in the center of the die, with the perimeter region 114 surrounding the active region. The perimeter region can be an inert or otherwise inactive region on the top surface of the die between the active region and the periphery 112 which contains the bonding pads 110. The bonding pads are metalized regions, each electrically connected through the die to a portion of the active region.

As can be seen in FIGS. 1 and 2, the cover, comprised of the transparent pane and the standoff, can surround and cover the active region, which leaves the bonding pads exposed. In FIG. 1 the die is further shown disposed in a lead frame 116. The lead frame supports the die and cover, and comprises a plurality of lead pads 118. Each lead pad can be electrically connected to lead 122. The leads 122 can be electrically connected to corresponding pads on a circuit board. Each lead pad 118 can be wire bonded to a corresponding one of the bonding pads 110 via a bond wire 120. The electrical connections between the lead pads 118 and the leads 122, as well as between the bonding pads 110 and their respective portions of the active region, can be accomplished with through-silicon techniques, including, for example, through-silicon vias.

FIG. 3 shows an exploded isometric view 300 of a cover for an electro-optical semiconductor device, in accordance with an embodiment. The transparent pane 102 sits atop the standoff 104. The height of the standoff can be varied in the manufacturing process, depending on the application, as will be described. The pane 102 can have a substantially uniform thickness, or it can be shaped to have desired optical refraction properties. The standoff can be formed of a curable resin, such as epoxy. The standoff material can be selected to have optical properties, such as light blocking or light reflecting properties, as may be desired for particular applications. Alternatively, the inside wall 302 can be treated for selected optical properties, such as by painting or selective plating.

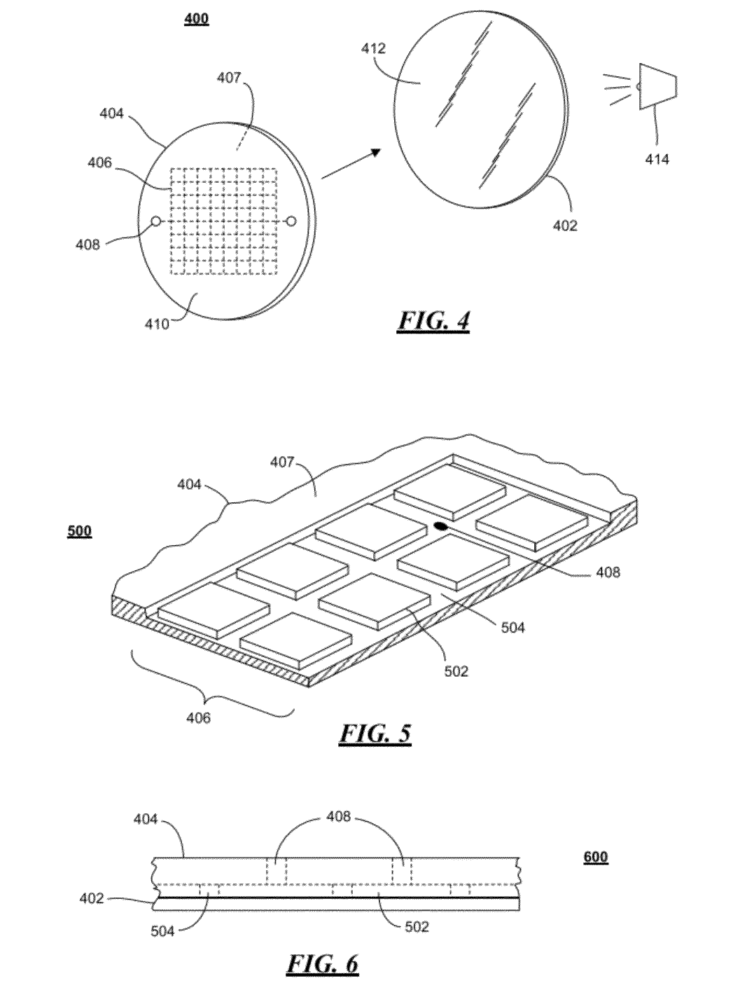

FIGS. 4-9 illustrate a process and means for creating covers for an electro-optical device, in accordance with an embodiment. FIGS. 406 illustrate a molding process. FIG. 4 shows diagram of a molding process 400 for creating a cover for an electro-optical semiconductor device, in accordance with one embodiment. FIG. 5 shows an isometric cut-away view 500 of a mold for creating a standoff for a cover for an electro-optical semiconductor device, in accordance with an embodiment. FIG. 6 shows a side elevational view 600 of a molding process for forming a cover for an electro-optical semiconductor device, in accordance with an embodiment.

A sheet 402 of transparent material is mated to a mold 404. The sheet can be optical grade glass or any other substantially transparent material as needed, depending on the application. The mold 404 comprises a grid 406 of channels 504 formed on the mating surface 407 (facing away, as shown) which mates against the sheet 402. One or more fill holes 408 form passages to the grid from the opposing side 410 of the mold 404. The grid of channels 504 form islands 502. The mold 404 is pressed against the sheet 402, where the mating surface 407 and the islands 502 are in contact with the mating surface 412 of the sheet 402, as shown in FIG. 6. The islands 502 exclude material injected into the mold channels from contacting the sheet 402. A curable material can then be injected into the mold 404 via the fill holes 408. One or more of the fill holes can be used to allow the injected material to escape in order to ensure an even distribution of the material throughout the channels 504. The mold 404 can be made of material which does not adhere to the curable resin, such as, for example, silicone. Once the curable material has been injected into the mold 404, it is cured while the mold 404 remains in contact with the sheet 402. The material can be cured, for example, by exposing it to a curing light or heat source 414 through the transparent material while the mold 404 remains pressed in contact with the sheet 402. For example, some types of epoxy can be cured by exposure to an ultraviolet light source. By cured it is meant that the material becomes sufficiently hard to work with further as described herein. The curable material adheres to the sheet 402, but not substantially to the mold 404. To facilitate non-adherence to the mold 404, the channels 504 can be coated with a mold release material, as is known, if necessary. Once the material is cured, the mold 404 can be separated from the sheet 402, leaving the cured resin on mating surface 412 of the sheet.

FIGS. 7-9 show the transparent sheet 402 with the cured material 702 forming a plurality of cells which are separated from each other to form individual covers.

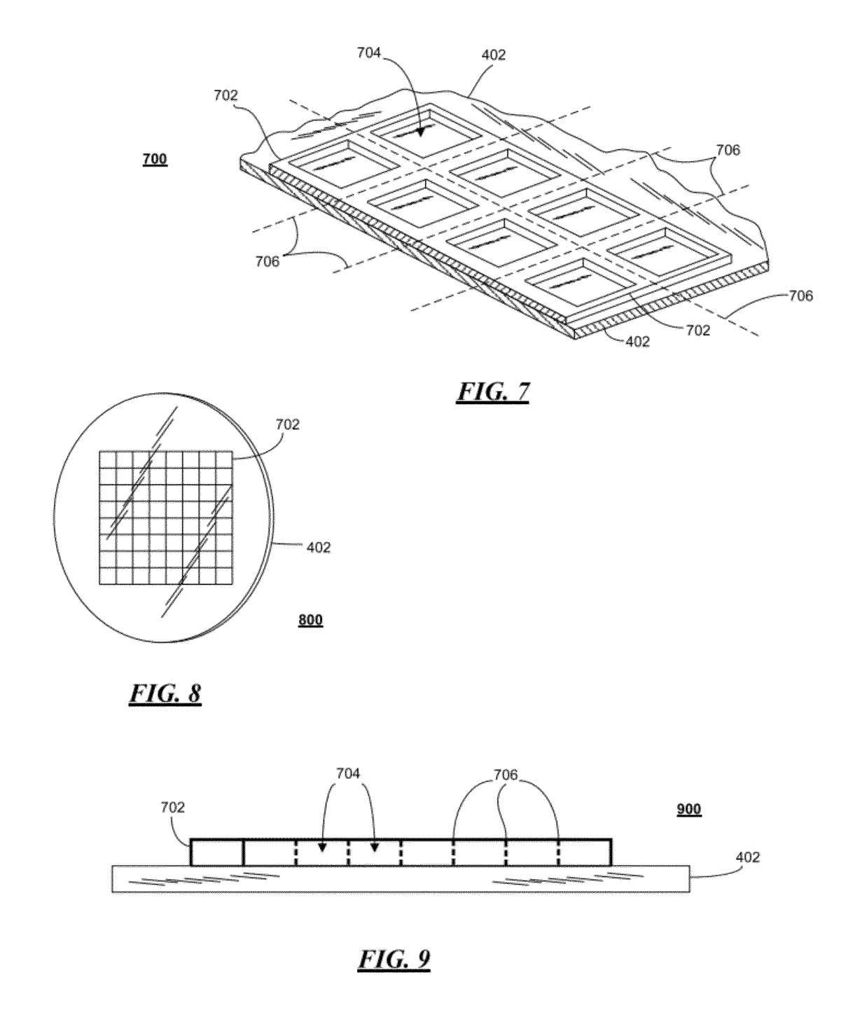

FIG. 7 shows an isometric cut-away view 700 of a grid of cells molded onto a sheet 402 of transparent material for creating a cover for an electro-optical semiconductor device, in accordance with an embodiment. FIG. 8 shows a top plan view 800 of a grid of cells molded onto a sheet 402 of transparent material for creating a cover for an electro-optical semiconductor device, in accordance with an embodiment. FIG. 9 shows a side elevational view 900 a grid of cells molded onto a sheet 402 of transparent material for creating a cover for an electro-optical semiconductor device, in accordance with an embodiment. The cells are formed by walls of the cured material 702, which corresponds to the channels 504. Each cell has a region 704 from which the curable material has been excluded, corresponding to the islands 502, and has an inner perimeter corresponding to the inner perimeter of the perimeter region of the dies. The cured material 702 is adhered to the sheet 402 material upon being cured. The sheet 402 and cured material can then be cut along cut lines 706 to separate the cells into individual covers, such as that shown in FIGS. 1-3, comprising a pane 102 and an standoff 104. The pane 102 is a section of the sheet 402, and the standoff 104 is formed by the cured material 702. The cells can be cut by conventional techniques, such as, for example, sawing the cells apart. Once separated, the covers can be aggregated for further assembly, such as by containing them in a way that facilitates pick and place operations so that each cover can be placed onto a die as illustrated in FIGS. 1-2.

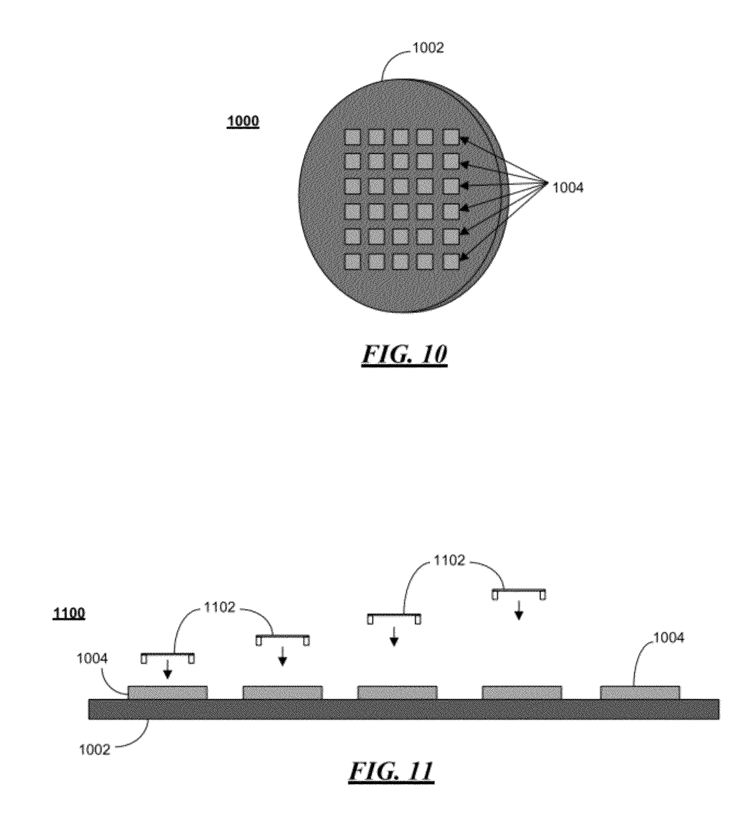

FIGS. 10-12 illustrate processes for assembling the covers onto the dies. FIG. 10 shows a top plan view 1000 of a semiconductor wafer 1002 containing a plurality of electro-optical dies, in accordance with an embodiment. FIG. 11 shows a side view 1100 of a process of placing covers on electro-optical semiconductor dies, in accordance with an embodiment. FIG. 12 shows a side view 1200 of a process of placing covers on electro-optical semiconductor dies, in accordance with an embodiment. The wafer 1002 is processed to form a plurality of electro-optical dies 1004. Each of the plurality of dies can be equivalent to die 106 of FIGS. 1-2. Semiconductor fabrication processes for forming multiple equivalent semiconductor devices (dies) on a single wafer are well known.

For each die 1004, a cover 1102 is placed on the die, as shown in FIGS. 1-2. The cover 1102 is comprised of a pane 102 and standoff 104. Each cover 1102 can be individually placed, as indicated in FIG. 11. For example, the covers, once separated, can be organized in trays, or placed on reels for pick and place operation. Each cover is adhered to its respective die via an adhesive that can be applied prior to placement of the cover on the die. FIG. 12 shows an alternative placement method of the covers onto dies 108 formed on a semiconductor wafer 1002. An adhesive 1202 is place on the perimeter region 114 on each die. Alternatively, the adhesive can be placed on the bottom surface of each standoff by an appropriate process. A placement tool comprised of a pick-up layer 1204 and a support member 1206 can be used to pick up a plurality of covers and place them all at once on their corresponding dies. The pick-up tool 1204 can be, for example, a vacuum tool comprised of a compliant material with holes for forming a vacuum seal between the compliant material and the pane 102 of each cover. The wafer 1002 can be situated on a holding tool 1208 which can be supported by support member 1210. The support member 1210 can be part of a conveyor mechanism which carried the holding tool 1208 to facilitate manufacture of packaged electro-optical semiconductor devices. Once each die on the wafer has had a cover placed on it as described, the dies can be separated for further manufacture processes, such as placement into a lead frame.

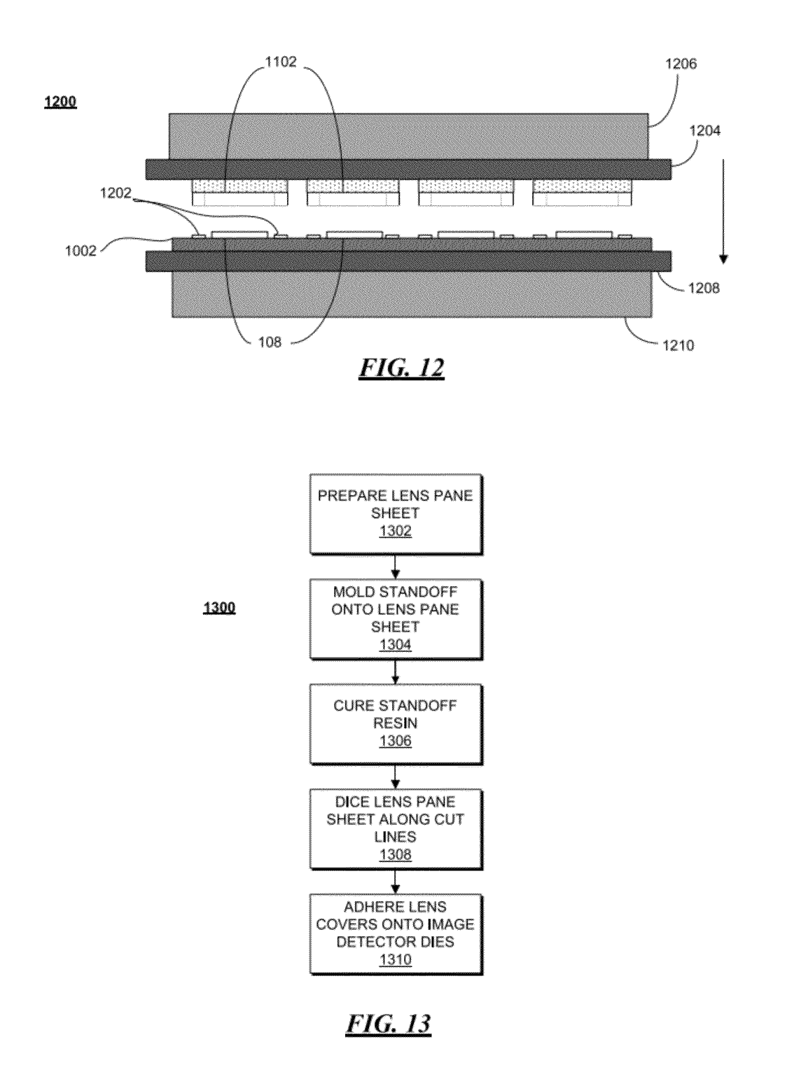

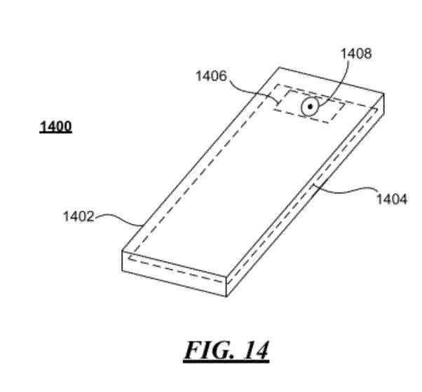

FIG. 13 shows a flow chart diagram 1300 illustrating, generally, a method of packaging an electro-optical semiconductor device, in accordance with an embodiment. The method commences by preparing a sheet of transparent material for processing. The sheet can be coated with appropriate optical coatings, such as, for example, an IR coating to substantially block IR light. The sheet is placed in an appropriate tool for the molding 1304 and curing processes 1306, as described, for example, in reference to FIGS. 3-6. Once the resin is cured, the sheet can be diced 1308 to separate the covers. The covers can be organized for placement on dies via an adhesive 1310. Once the covers are placed, each die can be tested by probing the bond pads, providing the necessary power and light sources, and comparing the resulting signals produced by the die with the expected results. The semiconductor wafer on which the dies have been fabricated can be diced to separate the dies for further processing. Testing can be performed before or after separating the dies from the wafer.

Once tested as needed, the dies can be wirebonded into appropriate lead frames. To protect the bond wires, it is contemplated that another resin can be applied to the die to cover and protect the bond wires 120 once the dies have been placed in lead frames and wirebonded. Since wirebonding occurs after the cover has been placed on the die, the active region is protected from dust and debris that may be produced during the wirebonding process. By protecting the active region of the electro-optical die, the wirebonding processing does not need to be as controlled as when the active region is exposed. Without having to be as careful during the wirebonding process as when the active region is exposed, the packaging and manufacture of electro-optical devices can be more cost effective.

FIG. 14 shows an isometric view of an electronic device 1400 including an electro-optical device packaged in accordance with an embodiment. The device shown is representative of a portable device such as, for example, a cellular phone, but the electro-optical device can be equally incorporated into many other devices, including laptop computers, monitors, and so on. The device has a housing 1402 to contain circuitry, and well as provide support for features such as input and output devices which can include keypads, graphical displays, and other such features (not shown). Disposed inside the housing is a circuit board 1404 which supports the electro-optical device 1406 which is disposed under a lens assembly 1408. The electro-optical device can be a device substantially as that illustrated in FIG. 1, mounted on the circuit board 1404. The lens assembly directs light onto the active region 108 of the image sensor die. The light passes through the pane 104 of the cover. The lens assembly can have a spherical aspect to refract and focus light, and may be provided in conjunction with an aperture, as is known. The electro-optical device can be mounted in a lead frame which is further connected to the circuit board, such as by a solder reflow process, or the die can be directly mounted on the board and wirebonded to pads on the board.

This invention can be embodied in other forms without departing from the spirit or essential attributes thereof. Accordingly, reference should be made to the following claims, rather than to the foregoing specification, as indicating the scope of the invention.

What is claimed is:

1. A method for packaging semiconductor image sensors, comprising:
forming a semiconductor image sensor wafer including a plurality of semiconductor image sensor dies, each die having an active region, a plurality of bonding pads disposed around a periphery of the die, and a perimeter region around the active region between the active region and the bonding pads;
molding a resin into a grid pattern on a sheet of transparent material, including curing the resin while in the mold, the grid pattern forming a plurality of cells, each cell bounded by a contiguous wall formed by the resin and having an inner perimeter corresponding to the perimeter region of the semiconductor image sensor dies;
separating the cells, each separated cell forming a cover having a transparent pane sectioned from the sheet of transparent material and a standoff attached to the pane which is formed by the cured resin; and
attaching each of the covers to one of the semiconductor sensor dies, wherein the standoff of each cover is attached to the perimeter region of its corresponding semiconductor image sensor die such that the active region of the die is under the pane and surrounded by the standoff, and the bonding pads remain exposed.

2. The method of claim 1, further comprising, subsequent to attaching the covers, testing semiconductor image sensor dies, including probing the bonding pads to measure a response of the active region to a test light source.

3. The method of claim 1, wherein attaching the covers to the semiconductor image sensor dies comprises adhering the standoff of each cover to the perimeter region of its corresponding semiconductor image sensor die.

4. The method of claim 1, further comprising, subsequent to attaching the covers, separating each semiconductor image sensor die from the semiconductor image sensor wafer.

5. The method of claim 1, further comprising, subsequent to attaching the covers, bonding a bonding wire from each bonding pad to one lead pad of a lead frame.

6. The method of claim 1, wherein molding the resin into the grid pattern comprises:
pressing a mating surface of a mold against the sheet of transparent material, the mold containing channels forming the grid pattern in the mating surface of the mold; and
injecting the resin into the channels.

7. The method of claim 6, wherein the resin is photocurable, curing the resin comprises exposing the resin to a curing light source through the transparent material.

8. The method of claim 1, further comprising providing an infrared filter layer on the sheet of transparent material.

9. The method of claim 1, further comprising, subsequent to separating the cells, placing each cover into an automated loader, and wherein attaching the covers is performed via an automated placement machine using the automated loader.

10. A semiconductor image detector package, comprising:
a semiconductor image sensor die, the die having a plurality of bonding pads disposed around a periphery of the die, an active region, and a perimeter region around the active region between the active region and the bonding pads;
a cover disposed over the active region, the cover have a transparent pane supported by and adhered to a standoff, the standoff having a shape corresponding to the perimeter region of the die, and wherein the standoff is adhered to the perimeter region.

11. The semiconductor image detector package of claim 10, wherein the semiconductor image sensor die is one of a plurality of such dies on a semiconductor image sensor wafer.

12. The semiconductor image detector package of claim 10, further comprising:
a lead frame supporting the semiconductor image sensor die having a plurality of lead pads corresponding to the plurality of bonding pads;
bond wires connecting each of the bonding pads to a corresponding one of the lead pads.

13. The semiconductor image detector package of claim 10, comprises an infrared filter layer on the transparent pane.

14. The semiconductor image detector package of claim 10, wherein the standoff is comprised of a cured resin.

15. The semiconductor image detector package of claim 14, wherein the cured resin is a photocurable resin.

16. The semiconductor image detector package of claim 10, wherein the cover is formed by:
providing a sheet transparent material;
molding a resin into a grid pattern on the transparent material, the grid pattern forming a plurality of cells, each cell bounded by a wall formed by the resin, an inner perimeter of each wall corresponding to an inner perimeter of the perimeter region of the die;
curing the resin in the mold; and
separating the cells into individual covers where the cured resin forms the standoff and the transparent material forms the transparent pane of each cover when separated.

17. An electronic device, comprising:
a housing;
a circuit board disposed within the housing;
an image detector disposed on the circuit board including:
a semiconductor image sensor die, the die having a plurality of bonding pads disposed around a periphery of the die, an active region, and a perimeter region around the active region between the active region and the bonding pads;
a cover disposed over the active region, the cover have a transparent pane supported by and adhered to a standoff, the standoff having a shape corresponding to the perimeter region of the die, and wherein the standoff is adhered to the perimeter region.

18. The electronic device of claim 17, wherein the standoff is a cured resin.

19. The electronic device of claim 18, wherein the cured resin is a photocurable resin.

20. The electronic device of claim 17, further comprising:
a lead frame supporting the semiconductor image sensor die having a plurality of lead pads corresponding to the plurality of bonding pads;
bond wires connecting each of the bonding pads to a corresponding one of the lead pads; and
wherein the lead frame comprises a plurality of leads, each of the leads electrically connected to one of lead pads, and each of the leads electrically coupled to the circuit board.
